(19) United States
(12) Patent Application Publication
(10) Pub. No.: US 2026/0058104 A1
(43) Pub. Date: Feb. 26, 2026

(54) SEMICONDUCTOR PROCESSING TOOL WITH HOT GAS PURGE

(71) Applicant: Taiwan Semiconductor Manufacturing Company, Ltd., Hsinchu (TW)

(72) Inventor: Ko-Chih Chen, Miaoli (TW)

(21) Appl. No.: 18/813,487

(22) Filed: Aug. 23, 2024

(51) Int. Cl. H01J 37/32; H01L 21/3065

(52) U.S. Cl. CPC H01J 37/32449; H01J 37/3299; H01J 2237/334; H01L 21/3065

(57) ABSTRACT

A semiconductor processing tool includes: a process chamber containing a wafer mount configured to hold a semiconductor wafer; a roughing pump; a pipe connecting the roughing pump to the process chamber; and a hot gas source configured to inject a hot gas into the pipe connecting the roughing pump to the process chamber. A method of semiconductor processing includes rough pumping a process chamber using a roughing pump and, during the rough pumping, injecting a hot gas into a pipe through which the roughing pump performs the rough pumping of the process chamber. After the rough pumping, semiconductor wafer processing is performed using the process chamber. During the semiconductor wafer processing, the process chamber is pumped using a high-vacuum pump backed by the roughing pump.

### BACKGROUND

The following relates to semiconductor processing, semiconductor processing tools, semiconductor etching tools, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of a semiconductor processing tool including hot gas purge piping.

FIG. 2 diagrammatically illustrates an enlarged exploded view of a portion of piping of the semiconductor processing tool of FIG. 1.

FIG. 3 diagrammatically illustrates operation of a hot gas purge to reduce buildup of byproduct on the inner wall of piping of a semiconductor processing tool.

FIG. 4 diagrammatically illustrates a sectional view of a pipe connected for hot gas purge at multiple connections around a circumference of the pipe.

FIG. 5 shows a flowchart of a semiconductor processing workflow employing a semiconductor processing tool including hot gas purge piping.

FIG. 6 diagrammatically illustrates a side sectional view of a semiconductor processing tool during rough pumping of the process chamber, in which hot gas purge is employed.

FIG. 7 diagrammatically illustrate a side sectional view of the semiconductor processing tool of FIG. 6 during performance of wafer processing.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor processing tools such as etching tools, deposition tools, photoresist stripping tools, and so forth often employ a process chamber that is evacuated to sub-atmospheric pressure, after which one or more process gases are flowed through the process chamber. In an etching or photoresist stripping tool, the process gas(es) react with material of the semiconductor wafer to etch and remove the material. In a deposition process, the process gas(es) directly deposit onto the wafer, or engage in one or more chemical reactions to deposit material on the semiconductor wafer. A carrier gas, such as nitrogen or hydrogen, may be flowed through the process chamber with the process gas(es) to facilitate uniform flow and distribution of the process gas(es). Some semiconductor processing tools employ radio frequency (RF) energy to ionize (at least a portion of) the process gas(es) to form a plasma. The ionized molecules (which, as used herein, may encompass individual atoms) of the plasma can facilitate and/or accelerate chemical reactions producing the etching, deposition, or other semiconductor wafer processing.

The semiconductor processing produces byproducts in the form of unused process gas(es) and/or reaction products. In the case of etching, for example, the byproducts may be produced by reaction of material of the semiconductor wafer with the process gas(es) producing a gas-phase reaction product. These byproducts may coat walls of the process chamber, and/or coat pipes flowing gas(es) away from the process chamber.

The semiconductor processing tool is expected to have a relatively high wafer throughput, with each run (that is, the workflow for processing each semiconductor wafer) involving rough pumping the process chamber down to the high vacuum at which the wafer processing is performed. During the semiconductor wafer processing, the process chamber is at high vacuum, such as below about 1×10⁻³ Torr (about 0.1 Pa) for many processes. During the rough pumping, the pressure and mass flow rate is higher, and so byproducts that had coated walls of the process chamber during previous runs can dislodge during the rough pumping and be removed through a pipe leading to a roughing pump used to perform the rough pumping. A portion of the byproducts may adhere to the pipe connecting the process chamber with the roughing pump, and over time this can lead to gradual buildup of solid material on the inner surfaces of the pipe. Periodically, the semiconductor processing tool may be taken offline for maintenance, including cleaning out any blockages in the pipe leading to the roughing pump, or replacing the pipe if the buildup is of a nature where cleaning it out is not practical. Such maintenance is tedious and occupies valuable time of semiconductor fabrication facility workers.

The buildup of byproduct contamination in the pipe leading from the process chamber to the roughing pump can be detrimental in other ways. For example, byproduct contamination buildup can interfere with flow conductance (or, equivalently, flow resistance) of the pipe, thus changing the pattern of gas flow in the process chamber. Increased flow resistance can also produce unnecessary additional load on the roughing pump. A portion of this pipe may also serve to connect the exhaust of the high-vacuum pump (for example, a turbomolecular pump in some cases) to the roughing pump during the actual wafer processing (at this stage the roughing pump serves as a backing pump for the turbomolecular pump), and so buildup of byproduct contamination can adversely impact the gas flow pattern during the actual wafer processing, which can lead to nonuniformity in the etching, deposition, or other processing across the surface of the semiconductor wafer being processed.

Disclosed herein are semiconductor processing tools, and corresponding workflows, which suppress buildup of byproduct contamination on the pipe leading from the process chamber to the roughing pump. This provides numerous advantages, such as: reduced frequency of downtime when the semiconductor processing tool is taken offline for maintenance, reduced load on the roughing pump; improved gas flow uniformity; improved run-to-run consistency of the gas flow pattern; and improved etching, deposition, or other process uniformity across the surface of the semiconductor wafer.

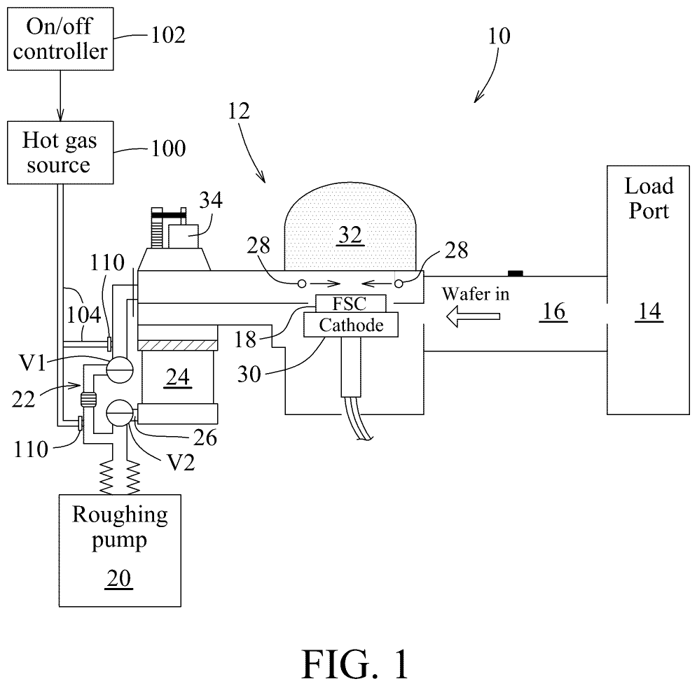

With reference to FIG. 1, a semiconductor processing tool 10 includes a process chamber 12, a load port 14 connected with the process chamber 12 by a wafer transfer pathway 16, a wafer mount 18, a roughing pump 20 connected with the process chamber 12 by a pipe 22, and a high-vacuum pump 24.

The roughing pump 20 is used to evacuate the process chamber 12 of the semiconductor processing tool 10 via the pipe 22 to a pressure sufficiently low for the high-vacuum pump 24 to operate efficiently. In some nonlimiting illustrative examples, the roughing pump 20 is a mechanical pump used to evacuate the process chamber of the semiconductor processing tool down to a pressure of about 1×10⁻³ Torr (about 0.1 Pa). The roughing pump 20 may be an oil-based roughing pump such as a rotary vane pump. If the semiconductor processing is sensitive to oil back-streaming from an oil-based roughing pump, then the roughing pump 20 may be a dry roughing pump such as a diaphragm pump, a scroll pump, a screw rotor pump, a dry piston pump, a sorption pump (utilizing liquid nitrogen to provide cryogenic pumping operation), a combination of two or more of these, or so forth.

The high-vacuum pump 24 may, by way of some nonlimiting illustrative examples, be a turbomolecular pump (i.e., turbo pump), a molecular drag pump, a diffusion pump, an ion pump, a cryogenic pump, a combination of two or more of these, or so forth. If the semiconductor processing is sensitive to oil contamination, then an oil-free high-vacuum pump 24 such as a turbomolecular pump may be used. The high-vacuum pump 24 operates at a high vacuum (i.e., lower pressure range) compared with the roughing pump 20. For example, some high-vacuum pumps operate most efficiently at a pressure of below 1×10⁻³ Torr (about 0.1 Pa). Moreover, for efficient operation of the high-vacuum pump 24, an exhaust 26 of the high-vacuum pump 24 is maintained at a pressure below atmospheric pressure (i.e., lower than about 760 Torr or 101 kPa) using a mechanical backing pump operating in conjunction with the high-vacuum pump 24. In the illustrative example, the backing pump that is connected to the exhaust 26 of the high-vacuum pump is the roughing pump 20, which is switched from rough pumping the process chamber 12 to backing the high-vacuum pump 24 by operation of a first valve V1 which controls connection of the pipe 22 to the process chamber 12, and a second valve V2 which controls connection of the exhaust 26 of the high-vacuum pump 24 to the pipe 22. While this illustrative example advantageously employs the same pump 20 for both rough pumping the process chamber 12 and backing the high-vacuum pump 24, it is alternatively contemplated to employ different pumps for the rough pumping and for backing the high-vacuum pump, respectively.

The process chamber 12 includes the wafer mount 18 which holds a semiconductor wafer to be processed (not shown). In some designs, the load port 14 and transfer pathway 16 are automated or robotic, so that (by way of one nonlimiting illustrative example) an overhead transport (OHT) loads a front-opening unified pod (FOUP) or other wafer carrier on the load port 14 and a robotic transfer mechanism of the transfer pathway 16 unloads successive semiconductor wafers from the wafer carrier into the process chamber 12 for processing. The wafer mount 18 may, for example, comprise an electrostatic chuck (ESC) 18, although any other suitable wafer mount can be used. The process chamber 12 further includes processing equipment, whose type and configuration depends on the type of semiconductor processing implemented by the semiconductor processing tool 10. In the nonlimiting illustrative example, the processing equipment of the process chamber 12 includes: gas inlets 28 via which one or more process gases flow into the process chamber 12, optionally along with a carrier gas such as hydrogen, nitrogen, forming gas (a mixture of nitrogen and hydrogen), argon, or another suitable carrier gas; electrodes such as an illustrative cathode 30 for producing a radio frequency (RF) field to ionize molecules of the process gas(es) to form a plasma; and a Dome Temperature Control Unit (DTCU) 32. The electrodes 30 are configured to generate an RF field in the process chamber 12 to produce a plasma, for example in embodiments in which the semiconductor processing tool is (or implements) a plasma etching tool, a deep reactive ion etching (DRIE) tool, or other type of plasma-assisted etching tool; or, in embodiments in which the semiconductor processing tool is (or implements) a plasma-enhanced chemical vapor deposition (PECVD) tool, a plasma ashing or stripping tool, or so forth. These are merely some nonlimiting illustrative examples. If the particular semiconductor process being implemented does not employ a plasma then the electrodes 30 may be omitted. The wafer processing equipment of the semiconductor processing tool may further include the Dome Temperature Control Unit 32, which includes heaters and temperature sensors (features not shown), and maintains a precise and uniform temperature for the semiconductor processing. The Dome Temperature Control Unit may optionally also provide active cooling after the semiconductor processing is complete, which can improve process precision and/or increase wafer throughput.

The semiconductor processing tool 10 may include other components depending on the type of processing being performed and other considerations. For example, the illustrative semiconductor processing tool 10 further includes a throttle valve 34 for controlling flow of gas out of an exhaust of the process chamber 12 (e.g., into the pipe 22 leading to the roughing pump 20).

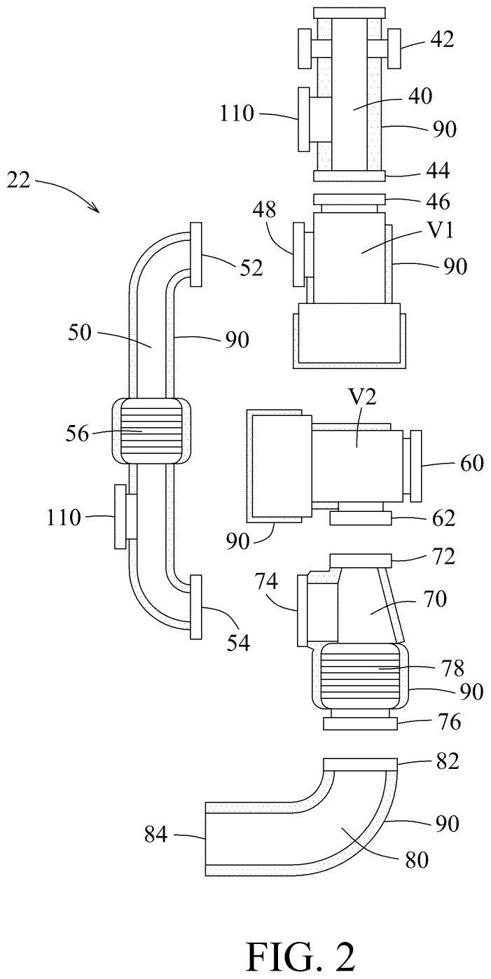

With continuing reference to FIG. 1 and with further reference to FIG. 2, the pipe 22 connecting the roughing pump 20 to the process chamber 12 is shown in an enlarged exploded view. In this nonlimiting illustrative example, the pipe 22 is constructed of several components. An upper pipe portion 40 has an upper connection flange 42 for connection to the process chamber 12, and a lower flange 44 that connects with a first flange 46 of the first valve V1. A U-shaped middle pipe portion 50 has an upper flange 52 that mates with a second flange 48 of the first valve V1, and a lower flange 54. The illustrative U-shaped middle pipe portion 50 also has an optional bellows 56 to provide positional flexibility in positioning the roughing pump 20 respective to the process chamber 12. The second valve V2 has a first flange 60 for connecting with the exhaust 26 of the high-vacuum pump 24, and a second flange 62. A T-coupler 70 has a first flange 72 that mates with the second flange 62 of the second valve V2, a second flange 74 that mates with the lower flange 54 of U-shaped middle pipe portion 50, and a third flange 76. The illustrative T-coupler 70 also has an optional bellows 78 to provide positional flexibility in positioning the roughing pump 20 respective to the high-vacuum pump 24. A lower pipe portion 80 has an upper flange 82 that mates with the third flange 76 of the T-coupler 70, and an opposite end 84 that extends to connect with the roughing pump 20. When rough pumping the process chamber 12, the first valve V1 is open and the second valve V2 is closed. In this configuration, the roughing pump 20 pulls on the process chamber 12 through the upper pipe portion 40, through the open first valve V1 into the U-shaped middle pipe portion 50, and thence through the T-coupler 70 into the lower pipe portion 80. When providing backing for the high-vacuum pump 24, the first valve V1 is closed and the second valve V2 is open. In this configuration, the roughing pump 20 pulls on the exhaust 26 of the high-vacuum pump 24 through the open second valve V2, through the T-coupler 70 into the lower pipe portion 80.

It is to be understood that the configuration of the pipe 22 connecting the roughing pump 20 to the process chamber 12 shown in FIG. 2 is a nonlimiting illustrative example, and numerous other plumbing configurations could be employed. For example, it may be noted that in FIG. 2 the lower pipe portion 80 is configured as an elbow, whereas in FIG. 1 the connection of the lower portion of the pipe 22 to the roughing pump 20 is a straight connection. This merely illustrates one possible variation in the shape and/or routing of the pipe 22 connecting the process chamber 12 and the roughing pump 20.

In general, most shapes and/or routings of the pipe 22 will include one or more curved or angled sections to facilitate routing of the pipe 22, and/or bellows (e.g., bellows 56 and 78) to provide strain relief, and/or one or more valves to control flow through the pipe 22 (e.g., valves V1 and V2), and/or other features that can impede gas flow and which can serve as traps for accumulation of byproducts or other solid material on the inner surfaces of the pipe 22. As previously noted, such buildup over time can constrict the flow and increase flow resistance of the pipe 22 (or equivalently, decrease flow conductivity), and in extreme cases can develop into a full blockage preventing gas flow through the pipe 22.

With continuing reference to FIG. 2, to suppress buildup of solid material on the inner surfaces of the pipe 22, such as from byproducts of the processing performed in the process chamber 12, a heater jacket 90 is disposed on an outside of the pipe 22 connecting the roughing pump 20 to the process chamber 12. The heater jacket 90 can take various forms. In one embodiment, the heater jacket 90 comprises a set of fitted heater jackets that are sized to closely fit around the components 40, 50, 60, 70, 80, and valves V1 and V2 of the pipe 22. Such a fitted heater jacket 90 includes resistive heater wire or the like disposed in electrical insulation, and the resistive heaters of the heater jacket portions fitted around the individual components 40, 50, 60, 70, 80, V1, and V2 of the pipe 22 may be electrically connected in series to be powered by electrical leads (details not shown). In other embodiments, the heater jacket 90 may comprise one or more heater tapes that are wrapped around the components 40, 50, 60, 70, 80, V1, and V2 of the pipe 22. The heater tape(s) similarly comprise a resistive heater embedded in electrical insulation such as silicone rubber insulation, fiberglass insulation, or so forth. In operation, the heater jacket 90 is disposed on the outside of the pipe 22, and the resistive heaters of the heater jacket 90 apply heat to the outside of the pipe 22. The pipe 22 is made of stainless steel or another metal or thermally conductive material, and the heat applied externally to the pipe 22 by the heater jacket 90 conducts to the inner surfaces of the pipe 22. This heat can increase kinetic energy of the molecules at the inside surfaces of the pipe 22 and thereby suppress adsorption of gas-phase molecules onto the inside surfaces of the pipe 22.

As recognized herein, the heater jacket 90 may be insufficient to suppress buildup over time of solid deposits on the inside surfaces of the pipe 22. The heat transfer from the outside of the pipe 22 to the inside reduces efficiency of heat transfer to the inside surfaces of the pipe 22. The heat applied from outside by the heater jacket 90 that does reach the inner surface of the pipe 22 can also be carried downstream by the flow of the gas through the pipe 22, especially during the rough pumping phase of the workflow when the volumetric gas flow (and hence heat capacity of the flowing gas) is relatively high. As previously mentioned, the rough pumping phase can also significantly contribute to transfer of solid deposits onto the inner surfaces of the pipe 22, due to the relatively high volumetric gas.

Additionally, there may be limitations on how hot the heater jacket 90 can be run, since it is on the external surface of the pipe 22 and hence presents a possible burn hazard for personnel working around the semiconductor processing tool 10. Still further, there may be limitations on how hot the portion of the heater jacket 90 surrounding the valves V1 and V2 and/or the bellows 56 and 78 can be run without damaging these components.

With continuing reference to FIG. 2 and with reference back to FIG. 1, in addition to (or, in other embodiments, instead of) employing the heater jacket 90 to suppress buildup over time of solid deposits on the inside surfaces of the pipe 22, the semiconductor processing tool 10 includes a hot gas purge system, which in the illustrative example of FIGS. 1 and 2 includes a hot gas source 100 controlled by an on/off controller 102, and hot gas piping 104 connected to flow hot gas from the hot gas source 100 to the pipe 22 that connects the process chamber 12 with the roughing pump 20. To implement the hot gas purging, the pipe 22 is modified by including additional inlet flanges 110 that connect with the hot gas piping 104 to enable injection of the hot gas from the hot gas source 100 into the pipe 22.

The hot gas produced by the hot gas source 100 is in some embodiments an inert gas that is heated to a temperature above room temperature. The source gas is nitrogen or argon in some nonlimiting illustrative embodiments. The source gas is heated by an in-line gas heater or other heat source to a target temperature T at a target flow rate F.

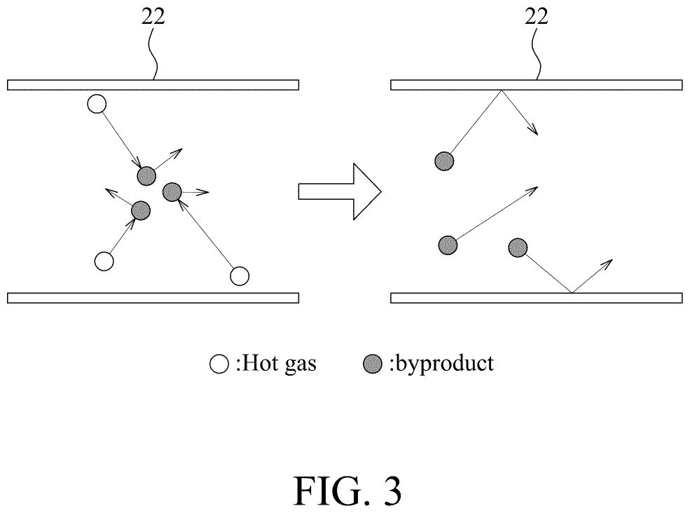

With reference to FIG. 3, operation of the hot gas purge to reduce buildup of byproduct on the inner wall of the pipe 22 of the semiconductor processing tool 10 is diagrammatically illustrated. The hot gas molecules have an average translational kinetic energy Ex that depends on the temperature T of the hot gas according to:

$${\overline{E}}_{k} = \frac{3}{2} k T \qquad ( 1 )$$

where again T is the temperature of the hot gas, and k is the Boltzmann constant and has a value of about k=1.38×10⁻²³ J/K. Hence, the kinetic energy of the molecules of hot gas scales linearly with the temperature (in Kelvin) of the hot gas. As diagrammatically shown in FIG. 3, the hot gas molecules impinge on byproduct molecules to increase the kinetic energy of the byproduct molecules, thus reducing the statistical likelihood of byproduct molecules adhering to the inner wall of the pipe 22 and thereby suppressing buildup. Moreover, the hot molecules may collide with byproduct molecules already adhered to the walls of the pipe 22 to dislodge them back into the gas flow for removal by the roughing pump 20.

Compared with the heater jacket 90, the hot gas purge has certain advantages. The hot gas is injected directly into the interior of the pipe 22 via the flanges 110, thus efficiently injecting heat into the interior of the pipe 22. The burn hazard is also reduced, since the heat needs to flow from the interior of the pipe 22 to its exterior to be able to come into contact with fabrication facility personnel. Kinetic energy transfer from the hot gas molecules to the byproduct molecules can also be more efficient at suppressing byproduct adhesion and buildup inside the pipe 22 compared with injection of heat from the heater jacket 90 by itself. Thus, the hot gas purge as disclosed herein advantageously reduces the frequency of cleaning and/or replacement of the pipe 22, reducing maintenance time and maintenance cost.

The temperature of the hot gas injected by the hot gas source 100 is higher than room temperature (i.e., higher than 25 Celsius degrees). The target temperature T of the hot gas can be chosen based on various design factors. In general, increasing the target temperature T increases the effectiveness of the hot gas purge in suppressing adhesion and buildup of byproduct on the interior walls of the pipe 22. The flow rate F of the hot gas also can impact the effectiveness. In general, a higher mass flow rate F increases the effectiveness of the hot gas purge in suppressing adhesion and buildup of byproduct on the interior walls of the pipe 22, due to a higher concentration of the hot gas molecules being injected into the pipe 22. However, if an in-line heater is used to heat the source gas (e.g., nitrogen or argon or another inert gas) to the target temperature T then the maximum attainable target temperature T may decrease with increasing flow rate F since higher flow rate F will reduce residency time of the source gas molecules in the flow path length of the in-line gas heater.

FIGS. 1 and 2 diagrammatically represent the inlet flanges 110 with respect to their placement along the direction of gas flow through the pipe 22. The illustrated two flanges 110 are strategically placed upstream of the respective two bends of the U-shaped middle pipe portion 50, and upstream of the respective first and second valves V1 and V2. This is advantageous, since buildup of byproduct on the walls of the pipe 22 is most likely at locations where the flow changes direction (e.g., bends) or passes through a constricted or non-smooth flow path (such as is sometimes present in the interior of a valve). While FIGS. 1 and 2 illustrate hot gas inlet flanges 110 at two locations along the flow path through the pipe 22, the number of locations of inlet flanges along the flow path through the pipe 22 can be one, two, three, four, or more.

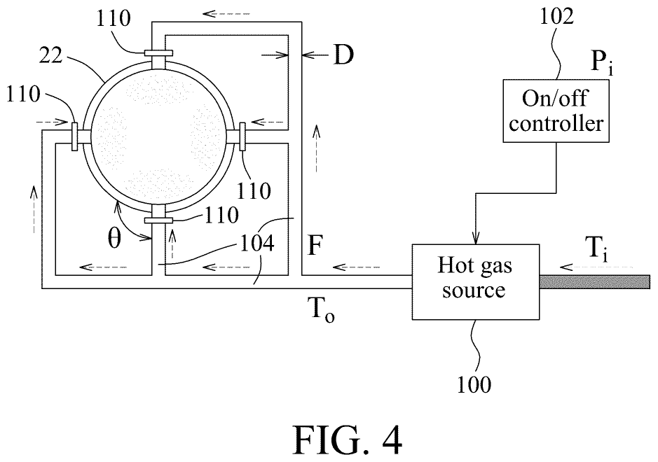

With continuing reference to FIGS. 1 and 2 and further reference now to FIG. 4, the number of hot gas inlet flanges 110 at a given location along the flow path through the pipe 22 can be one, two, three, four, or more. FIG. 4 diagrammatically illustrates a sectional view of a pipe connected for hot gas purge at multiple connections around a circumference of the pipe. The section plane of the view of FIG. 4 is perpendicular to the direction of gas flow through the pipe 22 (or, put another way, the normal vector of the section plane is parallel with the direction of gas flow through the pipe 22). As seen in FIG. 4, the pipe 22 has a circular perimeter, and there are four hot gas inlet flanges 110 spaced apart at 90° intervals around the circumference of the pipe 22. More generally, in some embodiments the hot gas may be injected into the pipe 22 at two or more locations around the circumference of the pipe 22. In some embodiments, the two or more locations around the circumference of the pipe 22 includes N locations (where N is an integer) angularly spaced at 360°/N intervals around the circumference of the pipe 22. So, for example, Table 1 provides suitable equidistant spacings of the hot gas inlet flanges 100 around the circumference of the pipe 22 for N=1, N=2, N=3, N=4, and N=5. Values of N greater than 5 (as well as N=1, i.e., a single hot gas inlet flange) are also contemplated. The benefit of having multiple hot gas inlet flanges around the circumference of the pipe 22 (and corresponding multiple injection locations around the circumference of the pipe 22) is that it provides a more uniform flow of the injected hot gas. This uniformity is enhanced if the multiple (i.e., N≥2) injection points are spaced at equidistant intervals (i.e., 360°/N) around the circumference of the pipe 22.

TABLE 1

| N | Angular spacing interval |
|---|---|
| 2 | 180° |
| 3 | 120° |
| 4 | 90° |
| 5 | 72° |

The hot gas purge may be performed at any time during usage of the semiconductor processing tool 10, and/or during an idle state of the semiconductor processing tool 10. In this regard, employing an inert gas (e.g., nitrogen or argon) as the hot gas has benefits insofar as the inert gas is unlikely to have deleterious impact on operation of the semiconductor processing tool 10 by way of undesirable chemical reactions involving the hot gas, for example if a small portion of the injected hot gas were to backstream into the process chamber 12. However, the hot gas purge consumes the inert gas and imposes a cost for heating the gas. Moreover, while the hot gas is an inert gas in some embodiments, if a small portion of the injected hot gas were to backstream into the process chamber 12 during wafer processing this could still have an adverse impact on uniformity of the wafer processing, for example by introducing a temperature gradient and/or modifying the gas flow of the process gas (and optional carrier gas) through the process chamber 12 during the wafer processing.

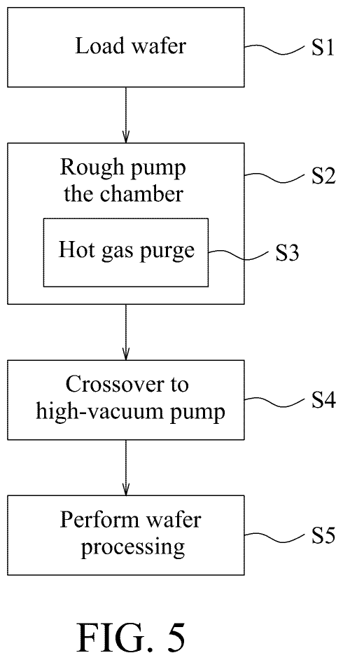

With reference to FIG. 5, to avoid any potential adverse impact on the wafer processing, in some embodiments the hot gas purge is only performed during rough pumping of the process chamber 12 prior to initiation of the wafer processing. FIG. 5 shows a high-level flow chart of a workflow for processing a wafer using the semiconductor processing tool 10. In an operation S1 (further referencing FIG. 1), the semiconductor wafer is transferred from the load port 14 (and more particularly from a FOUP or other wafer carrier disposed on or in the load port 14) to the process chamber 12 and automatically held by the electrostatic chuck 18 or other wafer holder within the process chamber 12. Typically, during this wafer transfer process the pressure in the process chamber 12 is higher than it will be during the wafer processing, e.g., the pressure in the process chamber 12 during the wafer loading may be at around atmospheric pressure. The transfer may optionally entail use of a load lock (not shown) to minimize contamination of the process chamber 12 during the wafer loading.

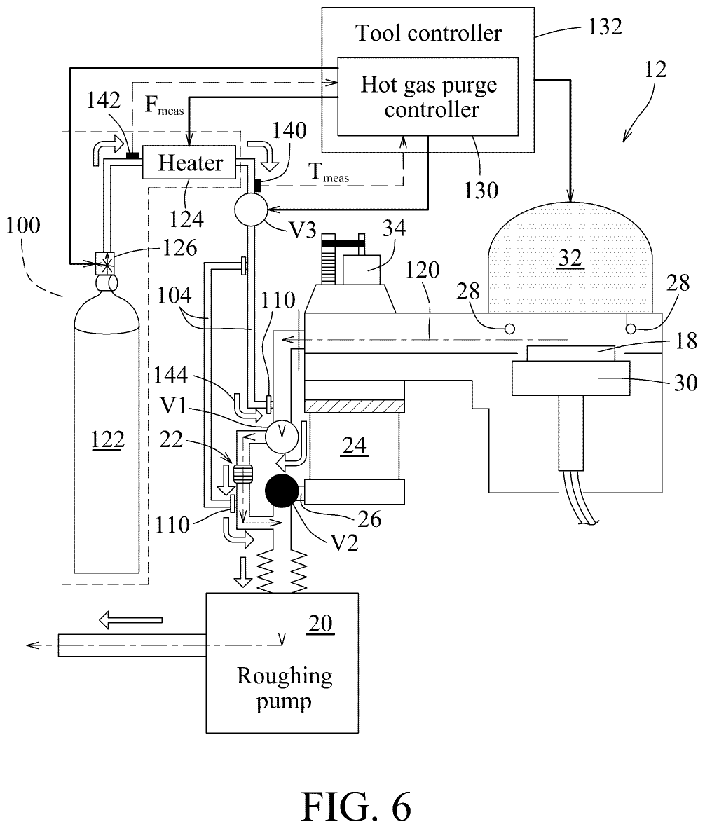

With continuing reference to FIG. 5 and with further reference to FIG. 6, in an operation S2 the process chamber 12 is rough pumped using the roughing pump 20. FIG. 6 diagrammatically illustrates a side sectional view of a portion of the semiconductor processing tool 10 during the rough pumping of the process chamber 12. To perform the rough pumping, the pipe 22 is configured as follows: the first valve V1 is open (diagrammatically indicated in FIG. 6 by representation of valve V1 as an open circle) to connect the exhaust of the process chamber 12 with the roughing pump 20 by way of the pipe 22; and the second valve V2 is closed (diagrammatically indicated in FIG. 6 by representation of valve V1 as a filled circle) to isolate the exhaust 26 of the high-vacuum pump 24 from the pipe 22. During the rough pumping, a gas flow 120 (diagrammatically indicated in FIG. 6 by arrows) flows from the process chamber 12 through the pipe 22 including through the open first valve V1 and into the roughing pump 20.

Additionally, as indicated in FIG. 5 a hot gas purge S3 is performed during the rough pumping S2 of the process chamber. This is diagrammatically shown in FIG. 6, which presents a more detailed nonlimiting illustrative embodiment of the gas purge system in which the gas source 100 is shown as including a source gas bottle 122 (for example, a nitrogen or argon cylinder 122) connected to an in-line gas heater 124, along with a mass-flow controller (MFC) 126 to control the mass flow rate of the source gas into the in-line gas heater 124. The in-line gas heater 124 may, for example, comprise a coil of gas tubing wound around a heater core and surrounded by a heater housing (details not shown). The coil of gas tubing increases residency time of the gas within the in-line gas heater 124 to increase the heating time to facilitate reaching the target temperature T of the hot gas. The heater core and/or housing may be heated by resistive heating or another heating mechanism (e.g., burning a flammable gas). These are merely some nonlimiting illustrative examples. Instead of the illustrative configuration employing the in-line gas heater 124, in another embodiment the gas source itself (e.g., gas cylinder 122) could be heated to the target temperature T. It is also noted that the source gas cylinder 122 is merely a nonlimiting illustrative example, and more generally the gas source could be different, such as a house nitrogen line of the semiconductor fabrication facility of the hot gas is heated nitrogen gas.

In some embodiments, the hot gas purge may operate in an open loop fashion. In the illustrative example of FIG. 6, however, feedback control is employed, using a hot gas purge controller 130 which in the illustrative example is integrated with a tool controller 132. The tool controller 132 may be implemented, for example, as a microprocessor, microcontroller, or the like programmed to control the robot of the transfer pathway 16 (see FIG. 1) actuators or other automatic features of the electrostatic mount 18, valves controlling the gas inlets 28, and so forth. The microprocessor, microcontroller, or the like is further programmed to implement the hot gas purge controller 130 to control the in-line gas heater 124 and/or the MFC 126 to obtain the target temperature T and target flow rate F. To provide the feedback, a temperature sensor 140 measures a temperature signal (Tₘₑₐₛ) indicative of the temperature of the hot gas exiting the in-line gas heater 124, and a flowmeter 142 measures a flow signal (Fₘₑₐₛ) indicative of the mass flow rate of source gas into the in-line gas heater 124. This is the measurement acquired by the flowmeter 142 positioned as shown, i.e., upstream of the in-line gas heater 124. Alternatively, the flowmeter 142 could be positioned downstream of the in-line gas heater 124, as the steady state mass flow rate into the in-line gas heater 124 should be the same as the steady state mass flow rate out of the in-line gas heater 124.) To provide the feedback temperature control, the heating applied by the in-line gas heater 124 can be increased if the temperature signal (Tₘₑₐₛ) indicates the hot gas is not hot enough, or decreased if the temperature signal (Tₘₑₐₛ) indicates the hot gas is too hot. Similarly, to provide the feedback flow control, the flow rate setting of the MFC 126 can be increased if the flow signal (Fₘₑₐₛ) indicates the hot gas flow is too low, or decreased if the flow signal (Fₘₑₐₛ) indicates the hot gas flow is too high. It is contemplated to provide only temperature control, or only flow rate control, or both temperature and flow rate control.

The hot gas purge system of FIG. 6 further includes a hot gas isolation valve V3, which is shown as open in FIG. 6 (indicated by representation of valve V3 as an open circle). The hot gas purge controller 130 may also operate the hot gas isolation valve V3 to perform the functionality of the on/off controller 102 of the embodiment of FIG. 1 (in addition to providing feedback control of temperature and/or mass flow rate). FIG. 6 illustrates the flow of the hot gas by open arrows 144 diagrammatically shown in FIG. 6.

With returning reference to FIG. 5, the rough pumping S2 continues until the pressure in the process chamber 12 reaches a crossover pressure, which is the pressure where the pumping efficiency of the roughing pump 20 is significantly reduced and/or the pumping efficiency (or operability) of the high-vacuum pump 24 is sufficient to begin pumping using the high-vacuum pump 24. The crossover pressure depends on the pumping characteristics of the two pumps 20 and 24, but is typically on the order of about 1×10⁻³ Torr (about 0.1 Pa). The hot gas purge S3 may continue for as long as the rough pumping S2 is performed, or the hot gas purge S3 may be shut off (e.g., by closing the hot gas isolation valve V3) some time before the crossover pressure is reached, since the additional hot gas flow as the pressure is approaching crossover may delay reaching the crossover pressure.

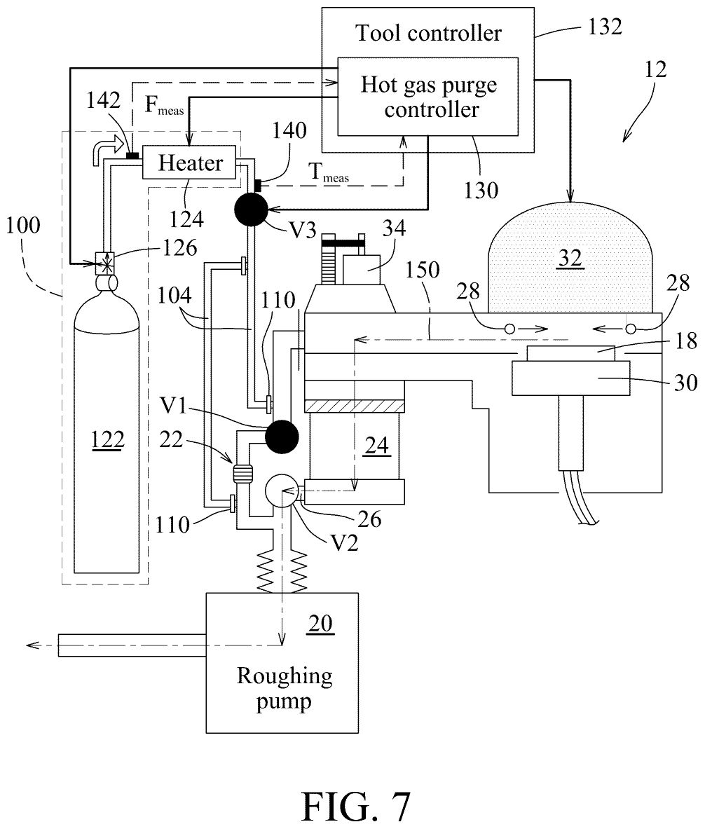

With continuing reference to FIG. 5 and with further reference to FIG. 7, when the crossover pressure is reached, in an operation S4 a crossover is performed to switch to pumping the process chamber 12 using a high-vacuum pump 24. As shown in FIG. 7, this entails closing the hot gas isolation valve V3 (if this has not been done previously), closing the first valve V1 to isolate the exhaust of the process chamber 12 from the pipe 22 (thus terminating operation of the roughing pump 20 for performing rough pumping of the process chamber 12), and opening the second valve V2 to connect the exhaust 26 of the high-vacuum pump 24 to the pipe 22 (thus initiating operation of the roughing pump 20 as the backing pump for operating the high-vacuum pump 24). Duc to closure of the hot gas isolation valve V3, the hot gas purge is now terminated. The process chamber 12 may continue to be pumped down using the high-vacuum pump 24 until the target pressure for performing the wafer processing is reached, at which point the workflow progresses to an operation S5 in which the wafer processing is performed (e.g., wafer etching, wafer deposition, or other wafer processing the semiconductor processing tool 10 is designed to perform).

During the wafer processing S5, a gas flow 150 (diagrammatically indicated in FIG. 7 by arrows) flows from the process chamber 12 through the high-vacuum pump 24, out the exhaust 26 of the high-vacuum pump 24 and through the open second valve V2 into (the lower portion of) the pipe 22 into the roughing pump 20 (which, again, is now operating as a backing pump for the high-vacuum pump 24).

In the following, some further embodiments are described.

In a nonlimiting illustrative embodiment, a method of semiconductor processing is disclosed. The method includes: rough pumping a process chamber of a semiconductor processing tool using a roughing pump; while rough pumping, flowing a hot gas through a pipe that connects the process chamber with the roughing pump; after the rough pumping, performing a crossover to switch to pumping the process chamber using a high-vacuum pump; and after the crossover and while pumping the process chamber using the high-vacuum pump, processing a semiconductor wafer disposed in the process chamber using the semiconductor processing tool.

In some embodiments, the flowing of the hot gas through the pipe that connects the process chamber with the roughing pump may include injecting the hot gas into the pipe at a location upstream of a bend of the pipe, wherein the hot gas injected upstream of the bend of the pipe flows through the bend of the pipe. In some embodiments, the flowing of the hot gas through the pipe that connects the process chamber with the roughing pump includes injecting the hot gas into the pipe at two or more locations around a circumference of the pipe, such as at N locations angularly spaced at 360°/N intervals around the circumference of the pipe, where N is an integer. In some embodiments, the performing of the crossover to switch to pumping the process chamber using the high-vacuum pump includes closing a hot gas isolation valve to isolate the hot gas from the pipe that connects the process chamber with the roughing pump. In some embodiments, the rough pumping is performed with a first valve disposed on the pipe that connects the process chamber with the roughing pump open and with a second valve that connects an exhaust of the high-vacuum pump with the pipe that connects the process chamber with the roughing pump closed, and the performing of the crossover includes closing the first valve and opening the second valve so that after the crossover the roughing pump is operatively connected as a backing pump for the high-vacuum pump. In some embodiments the method further includes, at least during the rough pumping, heating the pipe that connects the process chamber with the roughing pump using a heater jacket disposed on an outside of the pipe. In some embodiments, the processing of the semiconductor wafer includes performing plasma etching the semiconductor wafer. In some embodiments, the hot gas is generated by heating an inert gas to a temperature above room temperature using a heater. The method may further include measuring a temperature of the hot gas, and performing feedback control of the heating based on the measured temperature. The method may further include measuring a flow rate, which is of a flow of the source gas to the heater or of a flow of the hot gas from the heater, and performing feedback control of the flow of the source gas to the heater based on the measured flow rate.

In a nonlimiting illustrative embodiment, a semiconductor processing tool includes: a process chamber containing a wafer mount configured to hold a semiconductor wafer; a roughing pump; a pipe connecting the roughing pump to the process chamber; and a hot gas source configured to inject a hot gas into the pipe connecting the roughing pump to the process chamber.

In some embodiments, the semiconductor processing tool further includes a heater jacket disposed on an outside of the pipe connecting the roughing pump to the process chamber. In some embodiments, the semiconductor processing tool further includes a high-vacuum pump and a control system comprising an electronic processor and valves, the control system configured to switch between: a rough pumping configuration in which the roughing pump is operatively connected to evacuate the process chamber and the hot gas source is operatively connected to inject the hot gas into the pipe connecting the roughing pump to the process chamber, and a wafer processing configuration in which the roughing pump is operatively connected to an exhaust of the high-vacuum pump as a backing pump. In some embodiments, in the wafer processing configuration the hot gas source is not operatively connected to inject the hot gas into the pipe connecting the roughing pump to the process chamber.

In a nonlimiting illustrative embodiment, a method of semiconductor processing is disclosed. The method includes rough pumping a process chamber using a roughing pump and, during the rough pumping, injecting a hot gas into a pipe through which the roughing pump performs the rough pumping of the process chamber. After the rough pumping, semiconductor wafer processing is performed using the process chamber. During the semiconductor wafer processing, the process chamber is pumped using a high-vacuum pump backed by the roughing pump.

In some embodiments, at least during the rough pumping, heating the pipe through which the roughing pump performs the rough pumping of the process chamber using a heater jacket disposed on an outside of the pipe through which the roughing pump performs the rough pumping of the process chamber. In some embodiments, the method further includes generating the hot gas by heating an inert gas to a temperature above room temperature using a heater. In some embodiments, the method further includes measuring at least one parameter indicative of a temperature and/or flow rate of the hot gas, and performing feedback control of the generating based on the at least one parameter. In some embodiments, the injecting of the hot gas into the pipe through which the roughing pump performs the rough pumping of the process chamber includes injecting the hot gas into the pipe at three or more locations which are spaced apart around a circumference of the pipe through which the roughing pump performs the rough pumping of the process chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of semiconductor processing, the method comprising:
rough pumping a process chamber of a semiconductor processing tool using a roughing pump;
while rough pumping, flowing a hot gas through a pipe that connects the process chamber with the roughing pump;
after the rough pumping, performing a crossover to switch to pumping the process chamber using a high-vacuum pump; and
after the crossover and while pumping the process chamber using the high-vacuum pump, processing a semiconductor wafer disposed in the process chamber using the semiconductor processing tool.

2. The method of claim 1, further comprising:
generating the hot gas by heating an inert gas to a temperature above room temperature using a heater.

3. The method of claim 2, further comprising:
measuring a temperature of the hot gas; and
performing feedback control of the heating based on the measured temperature.

4. The method of claim 2, further comprising:
measuring a flow rate, wherein the flow rate is of a flow of the source gas to the heater or of a flow of the hot gas from the heater; and
performing feedback control of the flow of the source gas to the heater based on the measured flow rate.

5. The method of claim 1, wherein the flowing of the hot gas through the pipe that connects the process chamber with the roughing pump includes:
injecting the hot gas into the pipe at a location upstream of a bend of the pipe wherein the hot gas injected upstream of the bend of the pipe flows through the bend of the pipe.

6. The method of claim 1, wherein the flowing of the hot gas through the pipe that connects the process chamber with the roughing pump includes:
injecting the hot gas into the pipe at two or more locations around a circumference of the pipe.

7. The method of claim 6, wherein the two or more locations around the circumference of the pipe includes N locations angularly spaced at 360°/N intervals around the circumference of the pipe, where N is an integer.

8. The method of claim 1, wherein the performing of the crossover to switch to pumping the process chamber using the high-vacuum pump includes closing a hot gas isolation valve to isolate the hot gas from the pipe that connects the process chamber with the roughing pump.

9. The method of claim 1, wherein:
the rough pumping is performed with a first valve disposed on the pipe that connects the process chamber with the roughing pump open and with a second valve that connects an exhaust of the high-vacuum pump with the pipe that connects the process chamber with the roughing pump closed; and
the performing of the crossover includes closing the first valve and opening the second valve so that after the crossover the roughing pump is operatively connected as a backing pump for the high-vacuum pump.

10. The method of claim 1, further comprising:
at least during the rough pumping, heating the pipe that connects the process chamber with the roughing pump using a heater jacket disposed on an outside of the pipe.

11. The method of claim 1, wherein the processing of the semiconductor wafer includes performing plasma etching the semiconductor wafer.

12. A semiconductor processing tool comprising:
a process chamber containing a wafer mount configured to hold a semiconductor wafer;
a roughing pump;
a pipe connecting the roughing pump to the process chamber; and
a hot gas source configured to inject a hot gas into the pipe connecting the roughing pump to the process chamber.

13. The semiconductor processing tool of claim 12, further comprising:
a heater jacket disposed on an outside of the pipe connecting the roughing pump to the process chamber.

14. The semiconductor processing tool of claim 12, further comprising:
a high-vacuum pump; and
a control system comprising an electronic processor and valves, the control system configured to switch between:
a rough pumping configuration in which the roughing pump is operatively connected to evacuate the process chamber and the hot gas source is operatively connected to inject the hot gas into the pipe connecting the roughing pump to the process chamber, and
a wafer processing configuration in which the roughing pump is operatively connected to an exhaust of the high-vacuum pump as a backing pump.

15. The semiconductor processing tool of claim 14, wherein, in the wafer processing configuration, the hot gas source is not operatively connected to inject the hot gas into the pipe connecting the roughing pump to the process chamber.

16. A method of semiconductor processing, the method comprising:
rough pumping a process chamber using a roughing pump and, during the rough pumping, injecting a hot gas into a pipe through which the roughing pump performs the rough pumping of the process chamber; and
after the rough pumping, performing semiconductor wafer processing using the process chamber and, during the semiconductor wafer processing, pumping the process chamber using a high-vacuum pump backed by the roughing pump.

17. The method of claim 16, further comprising:
at least during the rough pumping, heating the pipe through which the roughing pump performs the rough pumping of the process chamber using a heater jacket disposed on an outside of the pipe through which the roughing pump performs the rough pumping of the process chamber.

18. The method of claim 16, further comprising:
generating the hot gas by heating an inert gas to a temperature above room temperature using a heater.

19. The method of claim 18, further comprising:
measuring at least one parameter indicative of a temperature and/or flow rate of the hot gas; and
performing feedback control of the generating based on the at least one parameter.

20. The method of claim 16, wherein the injecting of the hot gas into the pipe through which the roughing pump performs the rough pumping of the process chamber includes:
injecting the hot gas into the pipe at three or more locations which are spaced apart around a circumference of the pipe through which the roughing pump performs the rough pumping of the process chamber.
